(19) United States
(12) Patent Application Publication
(10) Pub. No.: US 2017/0094786 A1
(43) Pub. Date: Mar. 30, 2017

(54) PRINTED CIRCUIT BOARD AND METHOD OF MANUFACTURING THE SAME

(71) Applicant: SAMSUNG ELECTRO-MECHANICS CO., LTD., Suwon-si (KR)

(72) Inventors: Yu Hong OH, Suwon-si (KR); Ye Jun PARK, Suwon-si (KR); Jun Hyeon KIM, Suwon-si (KR); Jung Wook SEO, Suwon-si (KR); Young Joon OH, Suwon-si (KR); Jae Joon LEE, Suwon-si (KR); Byung Kun KIM, Suwon-si (KR)

(21) Appl. No.: 15/052,222

(22) Filed: Feb. 24, 2016

(30) Foreign Application Priority Data
Sep. 30, 2015 (KR) 10-2015-0138030

(51) Int. Cl. H05K 1/02; H05K 1/03; H05K 3/00; H05K 1/11

(52) U.S. Cl. CPC H05K 1/0298; H05K 1/111; H05K 1/0373; H05K 3/0014

(57) ABSTRACT

A printed circuit board according to the present invention includes at least one insulating layer and an interconnection. The insulating layer includes a first depression at an interface with the interconnection, and a second depression at a surface of the first depression.

### CROSS-REFERENCE TO RELATED APPLICATION

This application claims the benefit of priority to Korean Patent Application No. 10-2015-0138030, filed on Sep. 30, 2015 with the Korean Intellectual Property Office, the entirety of which is incorporated herein by reference.

### TECHNICAL FIELD

The present inventive concept relates to a printed circuit board and a method of manufacturing the same.

### BACKGROUND

As the electronics industry develops, demand for multi-functional, high-performance, and compact electronic components has rapidly increased. In addition, due to a tendency to fabricate light, thin, short, and small electronic components, a printed circuit board on which electronic components are mounted also needs to accommodate high-density circuit patterns so that a plurality of electronic devices may be integrated in a small area. As the circuit patterns of the printed circuit board decreases and interlayer spacing of the circuit narrows, reliability of products may be reduced due to failures such as dielectric loss or short circuits, or degradation in bonding strength between the circuit and an insulating layer. Accordingly, a photosensitive insulating film capable of forming a small-sized opening may be used in a printed circuit board (PCB), a semiconductor package substrate, a flexible printed circuit board (FPCB), or the like.

### SUMMARY

An aspect of the present disclosure provides a printed circuit board having superior warpage characteristics and high rigidity, and having improved reliability due to excellent bonding strength between an insulating layer and an interconnection, and a method of efficiently manufacturing the printed circuit board.

According to an aspect of the present disclosure, a printed circuit board may include at least one insulating layer and an interconnection. The insulating layer may include a first depression at an interface with the interconnection, and a second depression at a surface of the first depression.

The first depression may have a concave shape.

The second depression may have a concave shape.

In this case, the insulating layer may include fillers dispersed therein. The above-described double depression structure may have a shape corresponding to the filler. In addition, the filler may have a shape such that a plurality of beads are agglomerated, a cone shape protruding from a surface of a filler base, or a shape including a porous structure formed on the surface of the filler base.

According to another aspect of the present disclosure, a method of manufacturing the above-described structure includes removing a filler exposed on a surface of an insulating layer and forming an interconnection filling the portion in which the filler is removed.

### BRIEF DESCRIPTION OF DRAWINGS

The above and other aspects, features, and advantages will be more clearly understood from the following detailed description taken in conjunction with the accompanying drawings, in which:

FIG. 1 is a cross-sectional view schematically illustrating a printed circuit board according to an exemplary embodiment;

FIG. 2 illustrates an insulating layer and an interconnection (part A in FIG. 1) according to the exemplary embodiment of FIG. 1 in more detail;

FIG. 3 illustrates a detailed shape of a filler employed in the exemplary embodiment of FIG. 1;

FIGS. 4 through 7 illustrate detailed shapes of fillers according to modified embodiments of printed circuit boards;

FIG. 8 is a process diagram schematically illustrating a method of manufacturing a printed circuit board according to an exemplary embodiment.

### DETAILED DESCRIPTION

Hereinafter, embodiments will be described as follows with reference to the attached drawings.

The present inventive concept may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer, or section from another region, layer, or section. Thus, a first member, component, region, layer, or section discussed below could be termed a second member, component, region, layer, or section without departing from the teachings of the exemplary embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “upper,” or “above” other elements would then be oriented “lower,” or “below” other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular embodiments only and is not intended to be limiting. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, embodiments will be described with reference to schematic views illustrating embodiments. In the drawings, for example, due to manufacturing techniques and/or tolerances, modifications of the shape shown may be estimated. Thus, embodiments should not be construed as being limited to the particular shapes of regions shown herein, for example, to include a change in shape results in manufacturing. The following embodiments may also be constituted by one or a combination thereof.

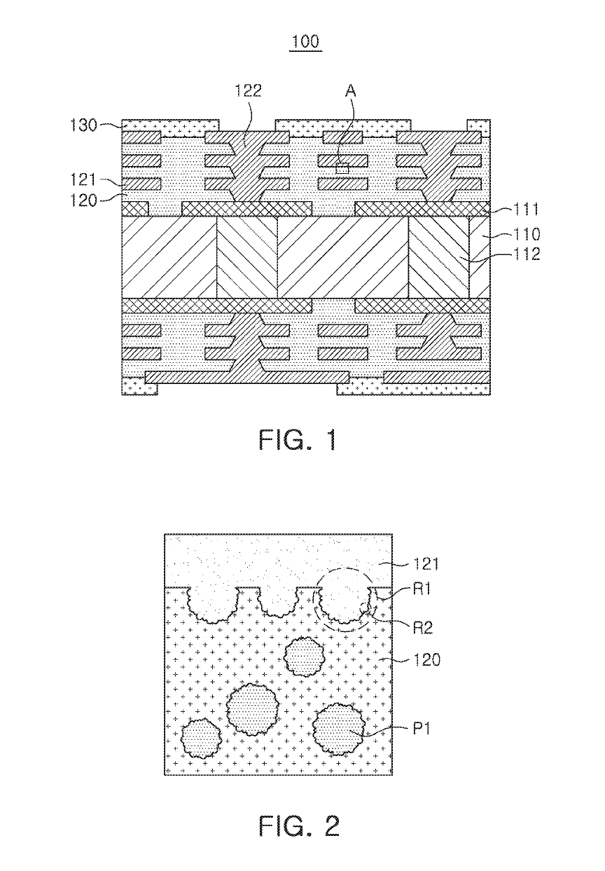

FIG. 1 is a cross-sectional view schematically illustrating a printed circuit board according to an exemplary embodiment. FIG. 2 is a view illustrating an insulating layer and interconnections (part A in FIG. 1) according to the exemplary embodiment of FIG. 1 in more detail.

Referring to FIG. 1, a printed circuit board 100 according to an exemplary embodiment may include an insulating layer 120 and an interconnection 121 and 122. The insulating layer 120 and the interconnection 121 and 122 may be disposed in both sides of a core structure 110. In this case, conductive patterns 111 and conductive vias 112 for electrical connection may be disposed in the core structure 110. However, the core structure 110 may be omitted in some embodiments, and other components of the printed circuit board 100, in particular, the insulating layer 120 and the interconnection 121 and 122, will hereinafter be mainly described in detail.

A plurality of insulating layers 120 may be stacked as illustrated in FIG. 1. In some exemplary embodiments, a single insulating layer 120 may configure a substrate. The insulating layer 120 may be formed of any material as long as it has electrically insulating properties. For example, a photosensitive resin, a thermosetting resin such as an epoxy resin, a thermoplastic resin such as polyimide, or a resin impregnated with a reinforcing material such as glass fibers or inorganic fillers, such as a pre-preg (PPG), may be used as the insulating layer 120. Of these materials, the photosensitive resin such as a photo imageable dielectric (PID) material may be used as the insulating layer 120, since it is easy to form micro patterns thereon compared to other materials and advantageous for fabricating a high-density printed circuit board.

The interconnection 121 and 122 may include a conductive pattern 121 and a conductive via 122, which are formed of a metal having high electrical conductivity, such as copper, nickel, or silver. As described above, when the insulating layer 120 is formed of a material including the photosensitive resin, micro patterns may be easily formed.

An outer layer 130 may include an opening exposing at least a portion of the conductive pattern 121 of the interconnection. The outer layer 130 may be, for example, formed of a solder resist, but is not limited thereto. The outer layer 130 may be formed of the same material as the insulating layer 120. The outer layer 130 is normally a single layer, but may be formed as a multilayer as needed.

As illustrated in FIG. 2, the insulating layer 120 may include a first depression R1 at an interface with the interconnection, more specifically, with the conductive pattern 121 of the interconnection according to the exemplary embodiment, and a second depression R2 at a surface of the first depression R1. That is, a double depression structure is formed in a surface of the insulating layer 120. The first depression R1 may have a concave shape. The second depression R2 may also have a concave shape.

In this case, the conductive pattern 121 may have a form that fills the first and second depressions R1 and R2, and due to such a double depression structure and a specific shape of the conductive pattern 121 combined therewith, the interface between the interconnection and the insulating layer 120 may be extended, and thus sufficient adhesion therebetween may be provided. The double depression structure disposed in the surface of the insulating layer 120 may be formed by removing specific shapes of fillers P1 having a rugged structure to be described below.

The insulating layer 120 includes the fillers P1 dispersed therein. As described above, the double depression structure of the insulating layer 120 may be formed in the process of removing the fillers P1 disposed in the surface of the insulating layer 120. Here, the fillers P1 disposed inside the insulating layer 120 may not be removed. The fillers P1 are formed of a material having a lower thermal expansion coefficient than the insulating layer 120, and thus serve to increase rigidity of the insulating layer 120 and contribute to improving warpage characteristics of a substrate. As an example of such a material, SiO₂, ZnO, Al₂O₃, BaSO₄, MgO, BN, SiC, AlBO₃, BaTiO₃, or CaZrO₃ may be used.

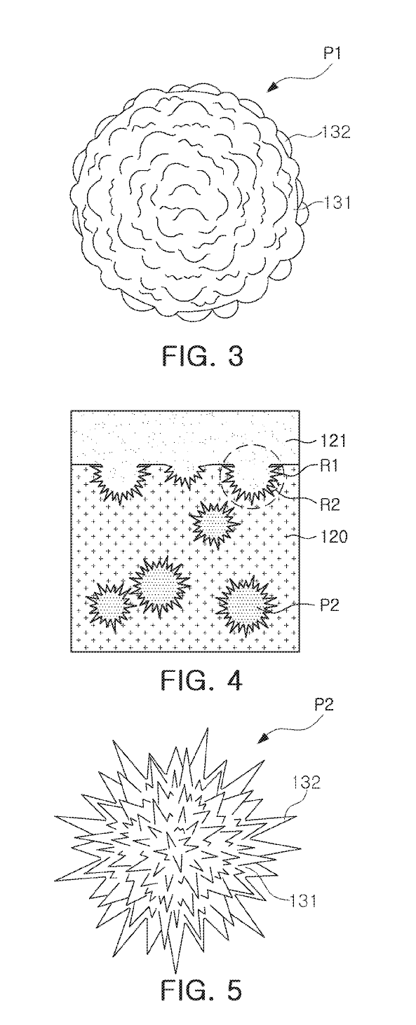

Although the fillers P1 serve to increase the rigidity of the insulating layer 120, bonding strength between the insulating layer 120 and the conductive pattern 121 may be weakened when portions of the fillers P1 included in the insulating layer 120 are exposed to the surface. According to the exemplary embodiment, the fillers P1 exposed to the surface of the insulating layer 120 are removed to maintain a depression structure in the surface of the insulating layer 120, and the fillers P1 further increase the bonding strength between the insulating layer 120 and the conductive pattern 121. A specific shape of a filler will be described with reference to FIG. 3.

More specifically, the filler P1 may be provided to have a shape such that filler ruggedness 132 is formed in a surface of a filler base 131. In this case, the filler base 131 has a spherical shape or a shape similar thereto. Accordingly, the first depression R1 has a shape corresponding to the filler base 131, and the second depression R2 has a shape corresponding to the filler ruggedness 132. In order to have such shapes, the filler P1 may have a shape such that a plurality of beads are agglomerated, as illustrated in FIGS. 2 and 3.

Other types of fillers and double depression structures of an insulating layer in accordance therewith will be described with reference to FIGS. 4 to 7. FIGS. 4 to 7 illustrate detailed shapes of fillers according to modified embodiments of printed circuit boards.

First, in a filler P2 according to an exemplary embodiment illustrated in FIGS. 4 and 5, filler ruggedness 132 formed in a surface of a filler base 131 may have a cone shape protruding from the surface of the filler base 131, that is, a shape similar to a sea urchin. Here, the filler base 131 may have a spherical shape or a shape similar thereto. A double depression structure capable of improving a bonding strength between an insulating layer 120 and a conductive pattern 121 may also be formed by the filler P2 in an interface between the insulating layer 120 and the conductive pattern 121.

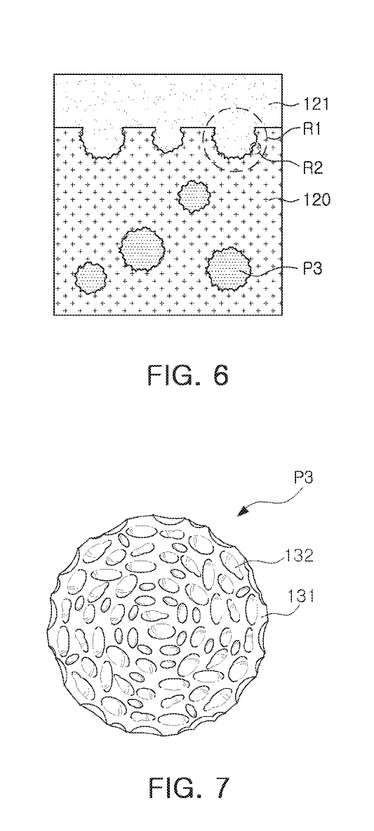

Next, in a filler P3 according to an exemplary embodiment illustrated in FIGS. 6 and 7, filler ruggedness 132 formed in a surface of a filler base 131 may have a porous structure formed in the surface of the filler base 131. Here, the filler base 131 may have a spherical shape or a shape similar thereto. A double depression structure capable of improving a bonding strength between an insulating layer 120 and a conductive pattern 121 may also be formed by the filler P3 in an interface between the insulating layer 120 and the conductive pattern 121.

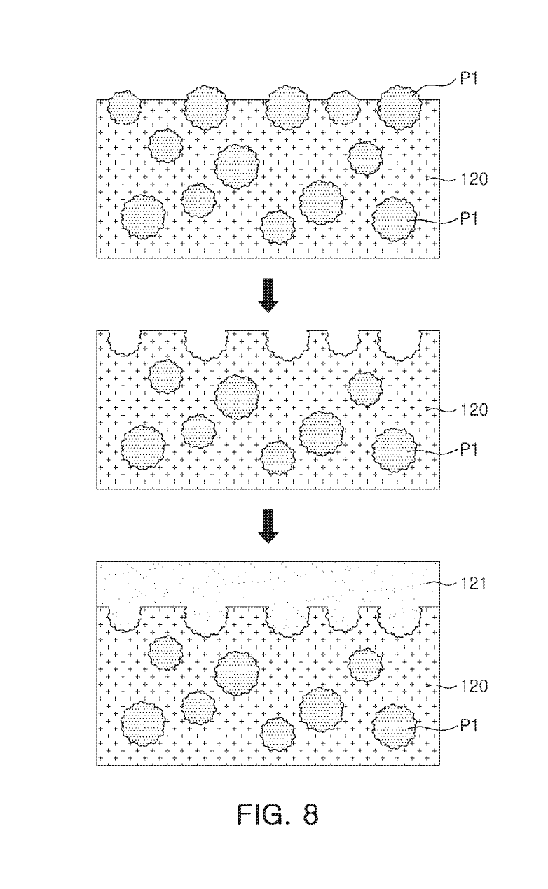

Hereinafter, a method of efficiently manufacturing the above-described printed circuit board will be described, focusing on a process of forming a double depression structure in an insulating layer. The above-described components will be understood in more detail by a description of the method of manufacturing the printed circuit board to be described below. FIG. 8 is a process diagram schematically illustrating a method of manufacturing a printed circuit board according to an exemplary embodiment. A process of forming a conductive via in an insulating layer or a process of forming a core may be performed by a substrate-forming process widely used in the art, and thus detailed descriptions thereof will be omitted.

Referring to FIG. 8, first, an insulating layer 120 in which fillers P1 are dispersed may be prepared. Here, the fillers P1 may have a shape such that filler ruggedness is formed in a surface of a filler base. In this case, portions of the fillers P1 may be exposed on a surface of the insulating layer 120. Even if the fillers P1 are not exposed in the process of forming the insulating layer 120, the fillers P1 may be exposed in a subsequent process. The fillers P1 according to the exemplary embodiment may be the fillers P1 illustrated in FIG. 3, and may be formed by agglomerating a plurality of beads formed of ZnO or the like. For example, the insulating layer 120 may be formed by coating a carrier film with the fillers P1 having a rugged structure together with an uncured photosensitive resin.

Next, a double depression structure including a first depression having a shape dished from a portion of the surface of the insulating layer 120 and a second depression structure having a shape dished from a surface of the first depression may be formed on the surface of the insulating layer 120 by removing at least a portion of the fillers P1 exposed on the surface of the insulating layer 120. The first and second depressions may be formed substantially at the same time by a single etching process. In this case, as described above, the first depression may have a shape corresponding to the filler base, and the second depression may have a shape corresponding to the filler ruggedness. The fillers P1 may be etched and removed by applying an acid used in a desmear process, for example.

Next, a conductive pattern 121 of the exemplary embodiment, which forms an interconnection, may be formed on the surface of the insulating layer 120. The conductive pattern 121 may fill the first and second depressions in the surface of the insulating layer 120 and thus form a stable bonding structure with the insulating layer 120. Here, the conductive pattern 121 may be formed by applying a conductive paste or by a plating process using a seed layer.

The insulating layer 120 and the conductive pattern 121 may be sequentially stacked, or may be simultaneously stacked after separately forming the insulating layer 120 and the conductive pattern 121.

Next, an outer layer 130 such as a solder resist may be formed on the outermost region of the printed circuit board. The outer layer 130 may have a shape suitable for use as an IC package substrate, and may have an appropriate shape depending on a design or a required function therefor.

As set forth above, according to the exemplary embodiment, a printed circuit board having improved bonding strength between an insulating layer and an interconnection can be provided by forming a double depression structure in an interface therebetween. In addition, a method of efficiently manufacturing a printed circuit board having the above-described structure can be provided.

While exemplary embodiments have been shown and described above, it will be apparent to those skilled in the art that modifications and variations could be made without departing from the scope of the invention as defined by the appended claims.

What is claimed is:

1. A printed circuit board, comprising at least one insulating layer and an interconnection,
wherein the insulating layer includes a first depression at an interface with the interconnection, and a second depression on a surface of the first depression.

2. The printed circuit board of claim 1, wherein the first depression has a concave shape.

3. The printed circuit board of claim 2, wherein the second depression has a concave shape.

4. The printed circuit board of claim 1, wherein the insulating layer includes fillers dispersed therein.

5. The printed circuit board of claim 4, wherein the fillers have a shape in which filler ruggedness is formed in a surface of a filler base.

6. The printed circuit board of claim 5, wherein the first depression has a shape corresponding to the filler base, and the second depression has a shape corresponding to the filler ruggedness.

7. The printed circuit board of claim 5, wherein the filler has a shape corresponding to an agglomerated plurality of beads.

8. The printed circuit board of claim 5, wherein the ruggedness formed in the surface of the filler base has a cone shape protruding from the surface of the filler base.

9. The printed circuit board of claim 5, wherein the ruggedness formed in the surface of the filler base has a porous structure formed in the surface of the filler base.

10. The printed circuit board of claim 5, wherein the filler base has a spherical shape.

11. The printed circuit board of claim 4, wherein the filler includes one or more selected from the group consisting of SiO₂, ZnO, Al₂O₃, BaSO₄, MgO, BN, SiC, AlBO₃, BaTiO₃, and CaZrO₃.

12. The printed circuit board of claim 1, wherein the interconnection has a shape filling the first and second depressions.

13. The printed circuit board of claim 12, wherein the interconnection includes a conductive pattern filling the first and second depressions.

14. The printed circuit board of claim 1, wherein the interconnection includes a conductive pattern and a conductive via.

15. The printed circuit board of claim 1, wherein the insulating layer includes a photosensitive material.

16. A method of manufacturing a printed circuit board, comprising:
forming an insulating layer in which fillers having a shape such that filler ruggedness is formed in a surface of a filler base are dispersed;
forming a first depression at a surface of the insulating layer and a second depression at a surface of the first depression by removing at least a portion of the fillers exposed on the surface of the insulating layer; and
forming an interconnection on a surface of the insulating layer.

17. The method of claim 16, wherein the first depression has a concave shape.

18. The method of claim 16, wherein the second depression has a concave shape.

19. The method of claim 16, wherein the first depression has a shape corresponding to the filler base, and the second depression has a shape corresponding to the filler ruggedness.

20. The method of claim 16, wherein the interconnection is formed to fill the first and second depressions.
